(19) United States
(12) Patent Application Publication
(10) Pub. No.: US 2007/0087951 A1
(43) Pub. Date: Apr. 19, 2007

(54) Thinner composition for inhibiting photoresist from drying

(75) Inventors: Geun Su Lee, Yongin-si (KR); Sam Young Kim, Gyeonggi-do (KR); Hee Sung Kim, Icheon-si (KR); Eung Kil Kang, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyeonggi-do (KR)

(21) Appl. No.: 11/417,558

(22) Filed: May 3, 2006

(30) Foreign Application Priority Data
Oct. 19, 2005 (KR) 10-2005-0098617
Dec. 30, 2005 (KR) 10-2005-0135112

(51) Int. Cl. G03F 7/42

(52) U.S. Cl. 510/176

(57) ABSTRACT

A thinner composition prevents photoresist from drying at the tip of a photoresist spraying nozzle during a semiconductor process. When the spraying nozzle is not used, the thinner composition that includes two or more solvents having a different volatility, specifically a mixture solvent including a first solvent consisting of an alkyl acetate compound and a second solvent consisting of an ether compound and that optionally comprises a third solvent consisting of a cycloketone, compound is contained in a solvent bath to induce volatilization of the thinner composition, thereby effectively inhibiting photoresist from drying.

### BACKGROUND OF THE DISCLOSURE

1. Field of the Disclosure

The disclosure relates to a thinner composition for inhibiting photoresist from drying at the tip of the photoresist spraying nozzle in a semiconductor process, and more specifically, to a thinner composition for keeping a nozzle which includes two or more solvents having a different volatility.

2. Description of the Related Technology

During a lithography process, a process for coating a photoresist film employs a rotation coating method for spraying a photoresist composition from a nozzle while rotating a wafer mounted on a track to enable a photoresist film to be evenly formed on the surface of the wafer by a centrifugal force.

Most ArF photoresist rapidly dry to powder, and the powder un-desirabley drops on a wafer during the semiconductor manufacturing process. Therefore the nozzle tip should be cleaned once every two days and it takes about two hours for cleaning. This frequent cleaning reduces throughput of process track and scanner.

When a photoresist spraying nozzle is not used in a semiconductor device manufacturing track, the nozzle is located in a solvent bath. A thinner composition is contained in the solvent bath, and the nozzle tip is not dipped in the thinner composition but located above the thinner composition at a predetermined distance, which causes volatilization of the thinner composition to inhibit photoresist from drying. However, it is not easy to inhibit photoresist from drying by the conventional thinner compositions because polymers are easily transformed into powder in case of ArF photoresist.

The currently used thinner composition includes PGMEA (propylene glycol monomethyl ether acetate), PGME (propylene glycol monomethyl ether), ethyl lactate, γ-butyrolactone, MMP (methyl 3-methoxy propionate). However, these solvents have a boiling point of over 118° C. to degrade the volatility as shown in Table 1.

TABLE 1

| | Boiling | | |
|---|---|---|---|
| | point | | Boiling point |
| Solvents | (° C.) | Solvents | (° C.) |
| PGME | 118˜119 | acetone | 56 |
| PGMEA | 145˜146 | 2-butanol | 98 |
| EL | 150˜154 | ethyl acetate | 76.5˜77.5 |
| MMP | 142˜143 | n-propyl acetate | 102 |
| butyrolactone | 204˜205 | n-butyl aceate | 124˜126 |
| DMF | 153 | anisole | 154 |
| (N,N-dimethylformamide) | | | |
| DMSO | 189 | cyclopentanoe | 130˜131 |
| (Dimethyl sulfoxide) | | | |
| IPA | 82.4 | cyclohexanone | 155 |
| (Isopropenyl acetate) | | | |

Most of the photoresist is dried within 1-7 days when using one of the solvents listed in Table 1, and the dried photoresist is dropped over the wafer, which causes defects (see Table 2).

TABLE 2

| | | Thinner | | | | | | | | | | |
|---|---|---|---|---|---|---|---|---|---|---|---|---|
| | | AZ EXP EBR1 | | | | | | | | EBR 70/30 | | |
| | | (manufactured by | | | HY ArF TH | | | | | (manufactured by | | |
| | | Clariant) | | | (manufactured by Dongjin) | | | | | Clariant) | | |
| | | Time | | | | | | | | | | |
| Nozzle | | 1 | 2 | 3 | 1 | 2 | 3 | 4 | 5 | 1 | 2 | 3 |
| No. | Photoresist | day | days | days | day | days | days | days | days | day | days | days |
| 1 | ARX1828J | ◯ | □ | □ | ◯ | ◯ | ◯ | □ | □ | ◯ | □ | □ |
| | (manufactured by JSR) | | | | | | | | | | | |
| 2 | TARF-P7039 | ◯ | ◯ | □ | ◯ | ◯ | ◯ | □ | □ | ◯ | ◯ | □ |
| | (manufactured by TOK) | | | | | | | | | | | |
| 3 | DHA-3604E | ◯ | □ | □ | ◯ | ◯ | □ | □ | □ | ◯ | ◯ | □ |
| | (manufactured by | | | | | | | | | | | |
| | Dongjin) | | | | | | | | | | | |
| 4 | AR1221J-21 | X | XX | □ | ◯ | ◯ | ◯ | □ | X | □ | □ | X |
| | (manufactured by JSR) | | | | | | | | | | | |
| 5 | SAIL-X121 | ◯ | ◯ | □ | ◯ | ◯ | ◯ | □ | □ | ◯ | ◯ | □ |
| | (manufactured by | | | | | | | | | | | |
| | Shinetstu) | | | | | | | | | | | |
| 6 | KUPR-A52T3G1 | ◯ | ◯ | □ | ◯ | ◯ | ◯ | ◯ | □ | ◯ | ◯ | ◯ |
| | (manufactured by Kumho) | | | | | | | | | | | |
| 7 | ARX2340J | ◯ | ◯ | □ | ◯ | ◯ | □ | □ | □ | ◯ | □ | □ |
| | (manufactured by JSR) | | | | | | | | | | | |
| 8 | DHA-H300T4X3 | X | X | XX | □ | □ | X | X | X | X | X | X |
| | (manufactured by | | | | | | | | | | | |
| | Dongjin) | | | | | | | | | | | |
| 9 | DHA-H300T4X16-1 | — | — | — | — | — | — | — | — | — | — | — |
| | (manufactured by | | | | | | | | | | | |
| | Dongjin) | | | | | | | | | | | |

| | | Thinner | | | | | | |
|---|---|---|---|---|---|---|---|---|
| | | LA 95 | | | | | | |
| | | (manufactured by TOK) | | | | | | |
| | | Time | | | | | | |
| Nozzle | | 1 | 2 | 3 | 4 | 5 | 6 | 7 |
| No. | Photoresist | day | days | days | days | days | days | days |
| 1 | ARX1828J | ◯ | ◯ | □ | □ | □ | □ | □ |
| | (manufactured by JSR) | | | | | | | |
| 2 | TARF-P7039 | ◯ | □ | □ | □ | □ | □ | □ |
| | (manufactured by TOK) | | | | | | | |
| 3 | DHA-3604E | ◯ | ◯ | □ | □ | □ | □ | □ |
| | (manufactured by | | | | | | | |
| | Dongjin) | | | | | | | |
| 4 | AR1221J-21 | ◯ | ◯ | □ | □ | □ | □ | X |
| | (manufactured by JSR) | | | | | | | |
| 5 | SAIL-X121 | ◯ | ◯ | ◯ | □ | □ | □ | □ |
| | (manufactured by | | | | | | | |
| | Shinetstu) | | | | | | | |
| 6 | KUPR-A52T3G1 | 1◯ | ◯ | ◯ | ◯ | ◯ | ◯ | ◯ |
| | (manufactured by Kumho) | | | | | | | |
| 7 | ARX2340J | ◯ | □ | □ | □ | □ | □ | □ |
| | (manufactured by JSR) | | | | | | | |
| 8 | DHA-H300T4X3 | □ | X | X | X | X | X | X |
| | (manufactured by | | | | | | | |
| | Dongjin) | | | | | | | |
| 9 | DHA-H300T4X16-1 | ◯ | ◯ | ◯ | ◯ | ◯ | ◯ | ◯ |
| | (manufactured by | | | | | | | |
| | Dongjin) | | | | | | | |

◯: good,
□: tip edge contamination, □: tip edge & outside contamination,
X: tip edge & outside & nozzle block contamination, and powder generation,
XX: tip edge & outside & nozzle block & bath contamination, and powder generation
Clariant: Clariant Ltd.
Dongjin: Dongjin Semichem Co., Ltd.
TOK: TOKYO OHKA KOGYO CO., LTD.
JSR: Japan Synthetic Rubber Co., Ltd.
Shinetsu: Shinetsu Chemical Industry Co., Ltd.
Kunmho: Kumho Petrochemical Co., Ltd.

Meanwhile, when a large amount of a solvent having a high volatility is used, a large amount of the volatilized solvent remains in the track, which can generate a spark and can cause a fire. As a result, it is necessary to minimize the use of highly volatile solvents.

### SUMMARY OF THE DISCLOSURE

Disclosed herein is a thinner composition that prevents photoresist from drying at the tip of a photoresist spraying nozzle during a semiconductor process. Generally, the composition includes an alkyl acetate compound and an ether compound. Also disclosed herein is a method for inhibiting photoresist from drying around the nozzle tip. The method includes preparing a solvent bath containing the thinner composition and keeping the nozzle positioned above the thinner composition when the nozzle is not in use.

### DETAILED DESCRIPTION OF THE PRESENTLY PREFERRED EMBODIMENTS

Disclosed herein is a thinner composition for inhibiting photoresist from drying. The composition includes two or more solvents having a different volatility, specifically, an alkyl acetate compound and an ether compound.

In this embodiment, there is provided a thinner composition for inhibiting photoresist from drying, which is obtained by mixing two or more solvents having a different volatility.

The thinner composition is prepared by mixing one or more of the alkyl acetate compound of Formula 1 and one or more of the ether compound of Formula 2a or 2b, as solvents having a different volatility.

The alkyl acetate compound is represented by Formula 1:
R₁COOR₂

wherein R₁ and R₂ are individually linear or branched C₁-C₁₀ alkyl, C₅-C₁₂ aryl or a C₆-C₁₈ alkylaryl group. Preferably, R₁ is linear C₁-C₃ alkyl group and R₂ is a linear C₁-C₅ alkyl group.

The ether compound is represented by Formula 2a:
R₃OR₄

wherein R₃ and R₄ are individually linear or branched C₁-C₁₀ alkyl, C₅-C₁₂ aryl or a C₆-C₁₈ alkylaryl group. Preferably, R₃ is linear C₁-C₃ alkyl and R₄ is a C₅-C₁₂ aryl group.

Alternatively, the ether compound is represented by Formula 2b:
R₆OR₅OR₇

wherein R₅ is linear or branched C₁-C₁₀ alkylene, C₅-C₁₂ arylene or a C₆-C₁₈ alkylarylene group, and R₆ and R₇ are individually linear or branched C₁-C₁₀ alkyl, C₅-C₁₂ aryl or a C₆-C₁₈ alkylaryl group. Preferably, R₅ is C₅-C₁₂ arylene, and R₆ and R₇ are individually linear C₁-C₃ alkyl.

Preferably, the compound of Formula 1 is one or more compounds selected from the group consisting of ethyl acetate, n-propyl acetate, n-butyl acetate, and pentyl acetate. Preferably, the compound of Formula 2a or 2b is one or more compounds selected from the group consisting of anisole, 1,3-dimethoxybenzene, and 1,4-dimethoxybenzene.

Preferably, the thinner composition includes the compound of Formula 1 in an amount ranging from 60 to 99 parts by weight, based on 100 parts by weight of the whole composition, and the compound of Formula 2a or 2b in an amount ranging from 1 to 40 parts by weight, based on 100 parts by weight of the whole composition.

The disclosed thinner composition may further comprises a cycloketone compound of Formula 3. 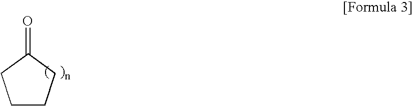
wherein n is an integer ranging from 0 to 5.

The compound of Formula 3 preferably includes cyclopentanone or cyclohexanone.

When the disclosed thinner composition includes the compound of Formula 3, the disclosed thinner composition includes the ether compound in an amount ranging from 10 to 44 parts by weight and the cycloketone compound in an amount ranging from 0.1 to 30 parts by weight, based on 100 parts by weight of the alkyl acetate compound.

The thinner composition is contained in a solvent bath for keeping a photoresist spraying nozzle when it is not used in a semiconductor process track, and used as a keeping solvent, thereby preventing photoresist from drying at the nozzle tip due to volatilization of the solvent.

When the solvent is mixed with other solvents having different volatility, the solvent is gradually volatilized and the volatilization is continued for a long time. Thus, the disclosed thinner composition is usefully employed in the current process system.

The disclosed thinner composition is more usefully employed, though not limited, in a process using (meth)acrylate type ArF photoresist than using KrF photoresist.

The (meth)acrylate type ArF photoresist polymer refers to a polymer comprising a repeating unit obtained by polymerizing (meth)acrylate monomer more than 50 wt %, based on the total weight of the polymer. Also, the (meth)acrylate type ArF photoresist polymer can be used in combination with other photoresist polymers, such as a norbomene type polymer or other (meth)acrylate type polymers.

Also disclosed herein is a method for inhibiting photoresist from drying around the nozzle tip. The method includes preparing a solvent bath containing the disclosed thinner composition. The method also includes keeping the nozzle positioned above the thinner composition contained in the solvent bath when it is not used.

Meanwhile, there is provided a solvent bath for keeping a photoresist spraying nozzle. The solvent bath includes the thinner composition.

Also, there is provided a photolithography device for manufacturing a semiconductor device. The photolithography device includes the solvent bath.

The disclosed compositions will be described in detail by referring to examples below, which are not intended to limit the present invention.

### EXAMPLE 1

### Preparation and Evaluation of a Disclosed Thinner Composition (1)

n-propyl acetate (18 L), anisole (1.3 L), and ethyl acetate (0.7 L) were mixed to obtain a disclosed thinner composition. Table 3 shows the photoresist drying phenomenon around the nozzle when the thinner composition was supplied in every 30 minutes.

TABLE 3

| | | Time | | | | | | | | | | | | |
|---|---|---|---|---|---|---|---|---|---|---|---|---|---|---|
| Nozzle | | 1 | 2 | 3 | 4 | 5 | 6 | 7 | 8 | 9 | 10 | 11 | 12 | 13 |
| No. | Photoresist | day | days | days | days | days | days | days | days | days | days | days | days | days |
| 1 | ARX1828J | ◯ | ◯ | ◯ | ◯ | ◯ | ◯ | ◯ | □ | □ | □ | □ | □ | □ |
| 2 | TARF-P7039 | ◯ | ◯ | ◯ | ◯ | ◯ | ◯ | ◯ | ◯ | ◯ | ◯ | ◯ | ◯ | □ |
| 3 | DHA-3604E | ◯ | ◯ | ◯ | ◯ | ◯ | ◯ | ◯ | □ | □ | □ | □ | □ | □ |
| 4 | AR1221J-21 | ◯ | ◯ | ◯ | ◯ | ◯ | ◯ | □ | □ | □ | □ | □ | □ | X |
| 5 | SAIL-X121 | ◯ | ◯ | ◯ | ◯ | ◯ | ◯ | ◯ | ◯ | ◯ | □ | □ | □ | □ |
| 6 | KUPR-A52T3G1 | ◯ | ◯ | ◯ | ◯ | ◯ | ◯ | ◯ | ◯ | ◯ | ◯ | ◯ | ◯ | ◯ |
| 7 | ARX2340J | ◯ | ◯ | ◯ | ◯ | ◯ | ◯ | ◯ | □ | □ | □ | □ | □ | □ |
| 8 | DHA-H300T4X3 | ◯ | ◯ | ◯ | ◯ | □ | □ | □ | □ | □ | □ | □ | X | X |
| 9 | DHA-H300T4X16-1 | ◯ | ◯ | ◯ | ◯ | ◯ | ◯ | ◯ | ◯ | ◯ | ◯ | ◯ | ◯ | ◯ |

◯: good,
□: tip edge contamination, □: tip edge & outside contamination,
X: tip edge & outside & nozzle block contamination, and powder generation,
XX: tip edge & outside & nozzle block & bath contamination, and powder generation

### EXAMPLE 2

### Preparation and Evaluation of a Disclosed Thinner Composition (2)

n-propyl acetate (10 L), n-butyl acetate (8 L), anisole (1.2 L), and ethyl acetate (0.8 L) were mixed to obtain a disclosed thinner composition. Table 4 shows the photoresist drying phenomenon around the nozzle when the thinner composition was supplied in every 30 minutes.

TABLE 4

| | | Time | | | | | | | | | | | | | |
|---|---|---|---|---|---|---|---|---|---|---|---|---|---|---|---|
| Nozzle | | 1 | 2 | 3 | 4 | 5 | 6 | 7 | 8 | 9 | 10 | 11 | 12 | 13 | 14 |
| No. | Photoresist | day | days | days | days | days | days | days | days | days | days | days | days | days | days |
| 1 | ARX1828J | ◯ | ◯ | ◯ | ◯ | ◯ | ◯ | ◯ | □ | □ | □ | □ | □ | □ | □ |
| 2 | TARF-P7039 | ◯ | ◯ | ◯ | ◯ | ◯ | ◯ | ◯ | ◯ | ◯ | ◯ | ◯ | ◯ | □ | □ |
| 3 | DHA-3604E | ◯ | ◯ | ◯ | ◯ | ◯ | ◯ | ◯ | □ | □ | □ | □ | □ | □ | □ |
| 4 | AR1221J-21 | ◯ | ◯ | ◯ | ◯ | ◯ | ◯ | □ | □ | □ | □ | □ | □ | □ | X |
| 5 | SAIL-X121 | ◯ | ◯ | ◯ | ◯ | ◯ | ◯ | ◯ | ◯ | ◯ | □ | □ | □ | □ | □ |
| 6 | KUPR-A52T3G1 | ◯ | ◯ | ◯ | ◯ | ◯ | ◯ | ◯ | ◯ | ◯ | ◯ | ◯ | ◯ | ◯ | ◯ |
| 7 | ARX2340J | ◯ | ◯ | ◯ | ◯ | ◯ | ◯ | ◯ | □ | □ | □ | □ | □ | □ | □ |
| 8 | DHA-H300T4X3 | ◯ | ◯ | ◯ | ◯ | □ | □ | □ | □ | □ | □ | □ | □ | □ | X |
| 9 | DHA- | ◯ | ◯ | ◯ | ◯ | ◯ | ◯ | ◯ | ◯ | ◯ | ◯ | ◯ | ◯ | ◯ | ◯ |
| | H300T4X16-1 | | | | | | | | | | | | | | |

◯: good,
□: tip edge contamination, □: tip edge & outside contamination,
X: tip edge & outside & nozzle block contamination, and powder generation,
XX: tip edge & outside & nozzle block & bath contamination, and powder generation

### EXAMPLE 3

### Preparation and Evaluation of a Disclosed Thinner Composition (3)

n-propyl acetate (18 L), cyclopentane (0.3 L), anisole (1.3 L), and ethyl acetate (0.4 L) were mixed at room temperature to obtain a disclosed thinner composition. Table 5 shows the photoresist drying phenomenon around the nozzle when the thinner composition was supplied in every 30 minutes.

TABLE 5

| | | Time | | | | | | | | | | | | |
|---|---|---|---|---|---|---|---|---|---|---|---|---|---|---|
| Nozzle | | 1 | 2 | 3 | 4 | 5 | 6 | 7 | 8 | 9 | 10 | 11 | 12 | 13 |
| No. | Photoresist | day | days | days | days | days | days | days | days | days | days | days | days | days |
| 1 | ARX1828J | ◯ | ◯ | ◯ | ◯ | ◯ | ◯ | ◯ | ◯ | □ | □ | □ | □ | □ |
| 2 | TARF-P7039 | ◯ | ◯ | ◯ | ◯ | ◯ | ◯ | ◯ | ◯ | ◯ | ◯ | ◯ | ◯ | ◯ |
| 3 | DHA-3604E | ◯ | ◯ | ◯ | ◯ | ◯ | ◯ | ◯ | ◯ | ◯ | □ | □ | □ | □ |
| 4 | AR1221J-21 | ◯ | ◯ | ◯ | ◯ | ◯ | ◯ | ◯ | ◯ | □ | □ | □ | □ | X |
| 5 | SAIL-X121 | ◯ | ◯ | ◯ | ◯ | ◯ | ◯ | ◯ | ◯ | ◯ | ◯ | □ | □ | □ |
| 6 | KUPR-A52T3G1 | ◯ | ◯ | ◯ | ◯ | ◯ | ◯ | ◯ | ◯ | ◯ | ◯ | ◯ | ◯ | ◯ |
| 7 | ARX2340J | ◯ | ◯ | ◯ | ◯ | ◯ | ◯ | ◯ | ◯ | ◯ | □ | □ | □ | □ |
| 8 | DHA-H300T4X3 | ◯ | ◯ | ◯ | ◯ | ◯ | □ | □ | □ | □ | □ | □ | X | X |
| 9 | DHA-H300T4X16-1 | ◯ | ◯ | ◯ | ◯ | ◯ | ◯ | ◯ | ◯ | ◯ | ◯ | ◯ | ◯ | ◯ |

◯: good,
□: tip edge contamination, □: tip edge & outside contamination,
X: tip edge & outside & nozzle block contamination, and powder generation,
XX: tip edge & outside & nozzle block & bath contamination, and powder generation

### EXAMPLE 4

### Preparation and Evaluation of a Disclosed Thinner Composition (4)

n-propyl acetate (10 L), n-butyl acetate (8 L), anisole (1.2 L), ethyl acetate (0.4 L), and cyclohexanone (0.4 L) were mixed to obtain a disclosed thinner composition. Table 6 shows the photoresist drying phenomenon around the nozzle when the thinner composition was supplied in every 30 minutes.

TABLE 6

| | | Time | | | | | | | | | | | | | |
|---|---|---|---|---|---|---|---|---|---|---|---|---|---|---|---|
| Nozzle | | 1 | 2 | 3 | 4 | 5 | 6 | 7 | 8 | 9 | 10 | 11 | 12 | 13 | 14 |
| No. | Photoresist | day | days | days | days | days | days | days | days | days | days | days | days | days | days |
| 1 | ARX1828J | ◯ | ◯ | ◯ | ◯ | ◯ | ◯ | ◯ | ◯ | □ | □ | □ | □ | □ | □ |
| 2 | TARF-P7039 | ◯ | ◯ | ◯ | ◯ | ◯ | ◯ | ◯ | ◯ | ◯ | ◯ | ◯ | ◯ | ◯ | ◯ |
| 3 | DHA-3604E | ◯ | ◯ | ◯ | ◯ | ◯ | ◯ | ◯ | ◯ | □ | □ | □ | □ | □ | □ |
| 4 | AR1221J-21 | ◯ | ◯ | ◯ | ◯ | ◯ | ◯ | ◯ | □ | □ | □ | □ | □ | □ | □ |
| 5 | SAIL-X121 | ◯ | ◯ | ◯ | ◯ | ◯ | ◯ | ◯ | ◯ | ◯ | ◯ | ◯ | □ | □ | □ |
| 6 | KUPR-A52T3G1 | ◯ | ◯ | ◯ | ◯ | ◯ | ◯ | ◯ | ◯ | ◯ | ◯ | ◯ | ◯ | ◯ | ◯ |
| 7 | ARX2340J | ◯ | ◯ | ◯ | ◯ | ◯ | ◯ | ◯ | ◯ | □ | □ | □ | □ | □ | □ |
| 8 | DHA-H300T4X3 | ◯ | ◯ | ◯ | ◯ | ◯ | □ | □ | □ | □ | □ | □ | □ | □ | □ |
| 9 | DHA- | ◯ | ◯ | ◯ | ◯ | ◯ | ◯ | ◯ | ◯ | ◯ | ◯ | ◯ | ◯ | ◯ | ◯ |
| | H300T4X16-1 | | | | | | | | | | | | | | |

◯: good,
□: tip edge contamination, □: tip edge & outside contamination,
X: tip edge & outside & nozzle block contamination, and powder generation,
XX: tip edge & outside & nozzle block & bath contamination, and powder generation

As shown in Tables 3 through 6, the photoresist drying phenomenon around the photoresist spraying nozzle was shown to be remarkably decreased when the disclosed thinner composition was supplied in the solvent bath.

In addition to the solvent combination of the above examples, the similar results to those of Examples 1 through 4 were obtained when various solvents in the range of the disclosure were mixed.

Except the mixture solvent, an additive may be further included in the disclosed thinner composition if necessary.

As described above, a disclosed thinner composition that includes two or more solvents having a different volatility, specifically a mixture solvent including an alkyl acetate compound, an ether compound and optionally a cycloketone compound is contained in a solvent bath for keeping a photoresist spraying nozzle to induce volatilization of the thinner composition, thereby effectively inhibiting photoresist from drying around the nozzle.

What is claimed is:

1. A thinner composition comprising an alkyl acetate compound and an ether compound.

2. The thinner composition according to claim 1, wherein the alkyl acetate compound is a compound represented by the Formula 1
R₁COOR₂ [Formula 1]
wherein R₁ and R₂ are individually linear or branched C₁-C₁₀ alkyl, C₅-C₁₂ aryl or a C₆-C₁₈ alkylaryl group; and
the ether compound is a compound represented by the Formula 2a or 2b
R₃OR₄ [Formula 2a]
wherein R₃ and R₄ are individually linear or branched C₁-C₁₀ alkyl, C₅-C₁₂ aryl or C₆-C₁₈ alkylaryl group;
R₆OR₅OR₇ [Formula 2b]
wherein R₅ is linear or branched C₁-C₁₀ alkylene, C₅-C₁₂ arylene or a C₆-C₁₈ alkylarylene group, and R₆ and R₇ are individually linear or branched C₁-C₁₀ alkyl, C₅-C₁₂ aryl or a C₆-C₁₈ alkylaryl group.

3. The thinner composition according to claim 1, wherein the alkyl acetate compound is present in an amount ranging from 60 to 99 parts by weight, based on 100 parts by weight of the composition, and the ether compound is present in an amount ranging from 1 to 40 parts by weight, based on 100 parts by weight of the composition.

4. The thinner composition according to claim 1, further comprising a cycloketone compound of Formula 3. 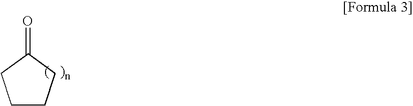
wherein n is an integer ranging from 0 to 5.

5. The thinner composition according to claim 4, wherein the thinner composition comprises the ether compound in an amount ranging from 10 to 44 parts by weight and the cycloketone compound in an amount ranging from 0.1 to 30 parts by weight, based on 100 parts by weight of the alkyl acetate compound.

6. The thinner composition according to claim 4, wherein the alkyl acetate compound is one or more compounds selected from the group consisting of ethyl acetate, n-propyl acetate, n-butyl acetate, and pentyl acetate; the ether compound is one or more compounds selected from the group consisting of anisole, 1,3-dimethoxybenzene, and 1,4-dimethoxybenzene; and the cycloketone compound is cyclopentanone or cyclohexanone.

7. The thinner composition according to claim 1, wherein the composition is contained in a solvent bath for keeping a photoresist spraying nozzle when it is not used in a semiconductor process track.

8. The thinner composition according to claim 1, wherein the photoresist comprises a (meth)acrylate type ArF photoresist polymer.

9. A method for inhibiting photoresist from drying around the nozzle tip, the method comprising:
preparing a solvent bath containing the thinner composition of claim 1; and
keeping the nozzle positioned above the thinner composition contained in the solvent bath when it is not used.
